(19) United States
(12) Patent Application Publication
(10) Pub. No.: US 2015/0236305 A1
(43) Pub. Date: Aug. 20, 2015

(54) METHOD FOR MANUFACTURING ORGANIC ELECTROLUMINESCENT DISPLAY DEVICE

(71) Applicant: Japan Display Inc., Tokyo (JP)

(72) Inventors: Yuko MATSUMOTO, Tokyo (JP); Toshihiro SATO, Tokyo (JP)

(21) Appl. No.: 14/627,374

(22) Filed: Feb. 20, 2015

(30) Foreign Application Priority Data
Feb. 20, 2014 (JP) 2014-030690

(51) Int. Cl. H01L 51/56; H01L 51/52; H01L 27/32; H01L 51/00

(52) U.S. Cl. CPC H01L 51/56; H01L 51/0096; H01L 51/5284; H01L 27/322; H01L 2251/566

(57) ABSTRACT

A circuit substrate is prepared. The circuit substrate has an anode, a cathode, an organic electroluminescent film sandwiched between the anode and the cathode, and a sealing film sealing the organic electroluminescent film. A color filter substrate is prepared. The circuit substrate and the color filter substrate are bonded together with an adhesive layer. In the step of preparing the color filter substrate, a plurality of color layers, each colored one of a plurality of colors, are disposed on a substrate, and an adhesive is then printed on the substrate so that the adhesive layer covering the plurality of color layers is formed.

### CROSS-REFERENCE TO RELATED APPLICATION

The present application claims priority from Japanese application JP2014-030690 filed on Feb. 20, 2014, the content of which is hereby incorporated by reference into this application.

### BACKGROUND OF THE INVENTION

1. Field of the Invention

The present invention relates to a method for manufacturing an organic electroluminescent display device.

2. Description of the Related Art

Organic electroluminescent display devices have an organic film sandwiched between an anode and a cathode. Most of the organic electroluminescent display devices have a stack of organic films, one of which is a light-emitting layer. Such an organic film, acting as a light-emitting layer, is formed uniformly across a plurality of pixels if the emission of light of a single color, such as white light, is needed.

JP 2006-32010 A discloses an organic electroluminescent display device that produces a multicolor display by a combination of white light-emitting organic electroluminescent elements and color filters.

In high-definition display devices, adjacent pixels get closer to each other as the pixels become finer. Thus, light generated in any pixel may undesirably enter the adjacent pixel. This may cause color crosstalk when the colors of adjacent pixels are different.

### SUMMARY OF THE INVENTION

It is an object of the present invention to prevent color crosstalk between adjacent pixels.

(1) A method for manufacturing an organic electroluminescent display device according to an aspect of the present invention includes the following steps. A circuit substrate is prepared. The circuit substrate has an anode, a cathode, an organic electroluminescent film sandwiched between the anode and the cathode, and a sealing film sealing the organic electroluminescent film. A color filter substrate is prepared. The circuit substrate and the color filter substrate are bonded together with an adhesive layer. In the step of preparing the color filter substrate, a plurality of color layers, each colored one of a plurality of colors, are disposed on a substrate, and an adhesive is then printed on the substrate so that the adhesive layer covering the plurality of color layers is formed. According to the present invention, the adhesive layer, which is formed by printing the adhesive, can be thinner. Such a thin adhesive layer places the circuit substrate and the color filter substrate closer to each other, thus making it harder for light generated in any pixel to enter the adjacent pixel. This can prevent color crosstalk between adjacent pixels.

(2) In the method according to the item (1), the adhesive may be slow curing, and the adhesive layer maybe cured after the circuit substrate and the color filter substrate are bonded together.

(3) In the method according to the item (1), the plurality of color layers may be formed by printing.

(4) In the method according to the item (1), the step of preparing the color filter substrate may further include forming a black matrix by printing.

(5) The method according to any one of the items (1) to (4) may further include the following steps. A multiple circuit substrate, which is yet to be cut into a plurality of circuit substrates, is prepared. A multiple color filter substrate, which is yet to be cut into a plurality of color filter substrates, is prepared. The multiple circuit substrate and the multiple color filter substrate are bonded together with the adhesive layer. The multiple circuit substrate and the multiple color filter substrate are then cut into a plurality of bonded pairs of the circuit substrate and the color filter substrate.

### BRIEF DESCRIPTION OF THE DRAWINGS

FIG. 1 is a cross-sectional view of an organic luminescent display device manufactured by a method according to an embodiment of the present invention;

FIG. 2 is a perspective view showing a multiple circuit substrate used in the present embodiment;

FIG. 3 is a diagram for explaining a process for manufacturing a multiple color filter substrate used in the present embodiment;

FIG. 4 is a diagram showing a large substrate, on which a plurality of color layers, each colored one of a plurality of colors, are disposed;

FIG. 5 is a diagram for explaining a process for forming a black matrix;

FIG. 6 is a cross-sectional view for explaining a process for forming an adhesive layer;

FIG. 7 is a perspective view for explaining the process for forming the adhesive layer;

FIG. 8 is a diagram for explaining a process for boding the multiple circuit substrate and the multiple color filter substrate with the adhesive layer; and

FIG. 9 is a diagram for explaining a process for cutting the multiple circuit substrate and the multiple color filter substrate.

### DETAILED DESCRIPTION OF THE INVENTION

An embodiment of the present invention will now be described with reference to the accompanying drawings.

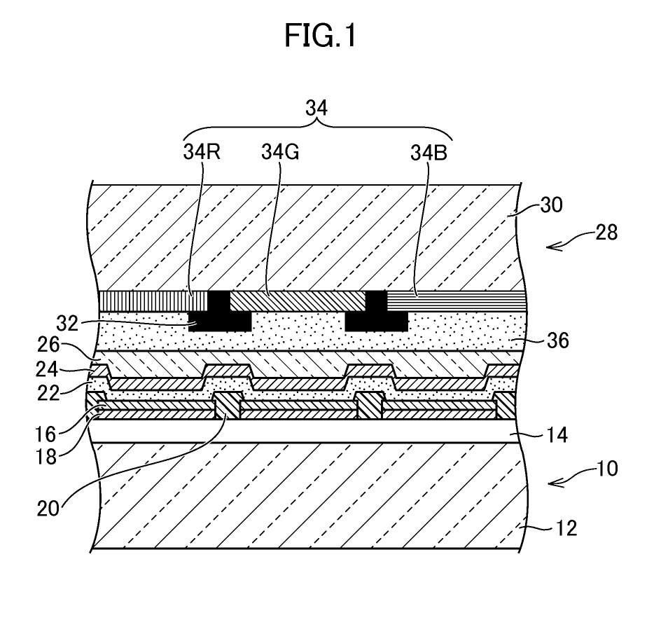

FIG. 1 is a cross-sectional view of an organic luminescent display device manufactured by a method according to the embodiment of the present invention.

The organic electroluminescent display device can be used in, for example, televisions, monitors for personal computers, laptop personal computers, personal digital assistants (PDAs), mobile phones, digital still cameras, digital video cameras, or monitors for car navigation systems.

The organic electroluminescent display device has a circuit substrate 10. The circuit substrate 10 includes a plurality of layers. One of the layers is a first substrate 12 made of, for example, glass. A circuit layer 14, including thin film transistors (not shown), is formed on the first substrate 12.

A plurality of anodes 16 are formed to couple to the source electrode or the drain electrode of the thin film transistors (not shown). Reflective layers 18, which reflect light, are located under the anodes 16. A bank layer 20 made of an insulator is formed so as to leave part of each anode 16 uncovered.

An organic electroluminescent film 22 is formed in contact with the anodes 16 through openings in the bank layer 20. The organic electroluminescent film 22 includes at least a light-emitting layer. What is known as such a structure is, for example, a laminate of a hole-injecting layer, a hole-transport layer, the light-emitting layer, an electron-transport layer, and an electron-injecting layer, in this order from the anodes 16. The organic electroluminescent film 22 is formed to continuously cover the anodes 16 and configured to emit white light.

A cathode 24 is formed on the organic electroluminescent film 22. The organic electroluminescent film 22 is covered with a sealing film 26 made of, for example, an inorganic material, such as SiN, SiO, or SiON.

The organic electroluminescent display device has a color filter substrate 28. The color filter substrate 28 is separated from the circuit substrate 10 to face the side of the circuit substrate 10 near the organic electroluminescent film 22. The color filter substrate 28 includes a plurality of layers. One of the layers is a second substrate 30 made of, for example, glass.

A black matrix 32 and a plurality of color layers 34 are formed in a portion of the color filter substrate 28 near the circuit substrate 10. The color layers 34 include color layers 34R, 34G, and 34B each colored one of a plurality of colors, such as red, green, and blue. The black matrix overlaps with edges of the color layers 34. The color layers 34 enables the organic electroluminescent display device to display images in full color, although the light generated in the organic electroluminescent film 22 is white.

The circuit substrate 10 and the color filter substrate 28 are bonded together with an adhesive layer 36. Specifically, the adhesive layer 36 interposes between the sealing film 26 of the circuit substrate 10, and the black matrix 32 and the color layers 34 of the color filter substrate 28. The adhesive layer 36 with a large thickness may cause light generated in any pixel to undesirably enter the adjacent pixel. To solve this problem, the adhesive layer 36 is formed thinner in this embodiment.

The following describes a method for manufacturing the organic electroluminescent display device according to the embodiment of the present invention.

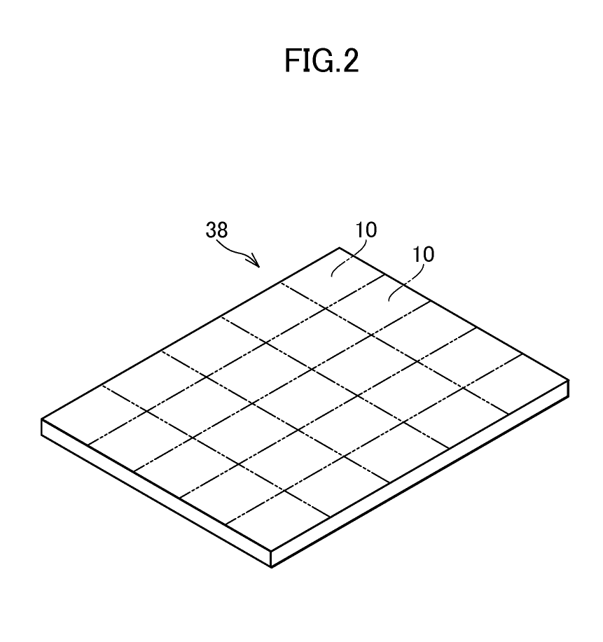

FIG. 2 is a perspective view showing a multiple circuit substrate used in the present embodiment. A multiple circuit substrate 38 is yet to be cut into a plurality of circuit substrates 10 (see FIG. 1). The multiple circuit substrate 38 has the organic electroluminescent film 22 shown in FIG. 1, and the anodes 16 and the cathode 24, between which the organic electroluminescent film 22 is sandwiched, in each area to be the circuit substrate 10. The multiple circuit substrate 38 has the sealing film 26 (see FIG. 1) spreading over the entire area to be the plurality of circuit substrates 10. The sealing film 26 seals the organic electroluminescent film 22. The process for manufacturing the multiple circuit substrate 38 is so well known that no further description of it is provided herein.

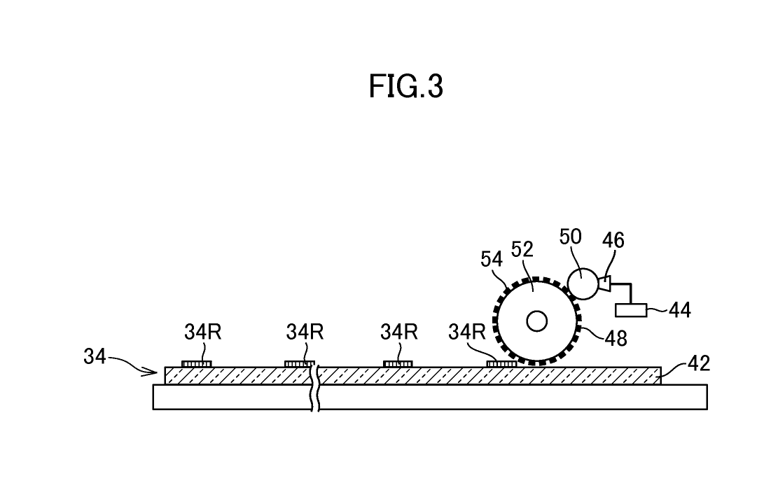

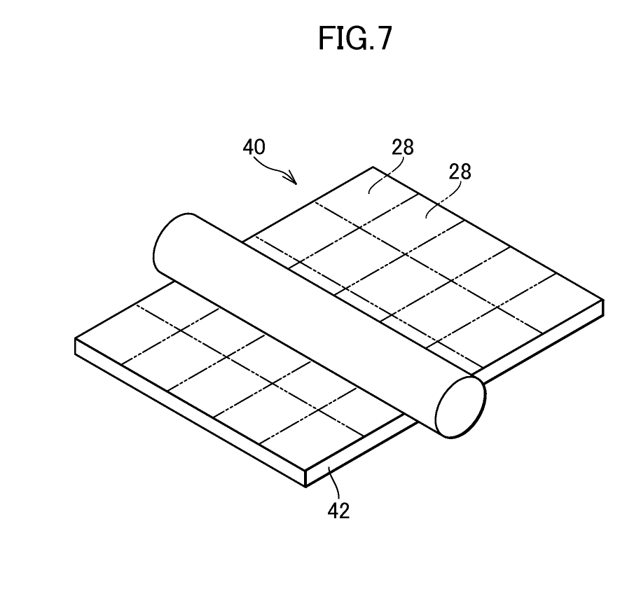

FIGS. 3 to 5 are diagrams for explaining a process for manufacturing a multiple color filter substrate used in the present embodiment. A multiple color filter substrate 40 (see FIG. 7) is yet to be cut into a plurality of color filter substrates 28. As shown in FIG. 3, a large substrate 42 is prepared for manufacture of the multiple color filter substrate 40. The large substrate 42 is yet to be cut into a plurality of second substrates 30 (see FIG.

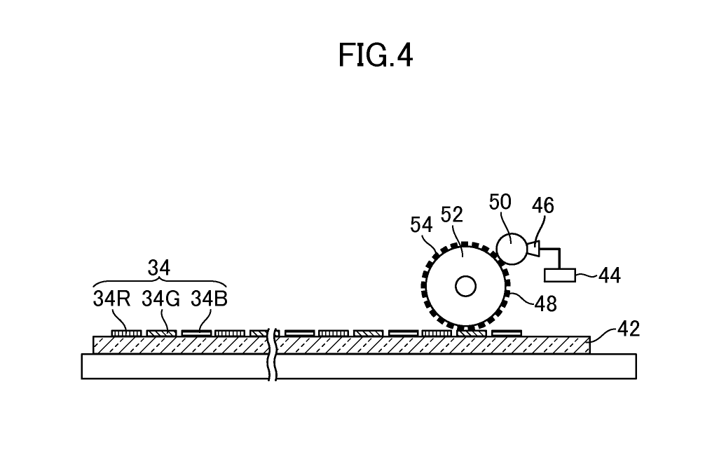

1). The plurality of color layers 34, each colored one of the plurality of colors, are disposed on the large substrate 42 by printing. When flexographic printing is used in the process, an ink 48, supplied from an ink tank 44 to an ink chamber 46, is applied to a flexographic printing plate 54 on a printing cylinder 52 via an anilox roll 50 for adjusting the amount of ink, and then transferred to the large substrate 42. The color layers 34R of a first color are thus formed. As shown in FIG. 4, the color layers 34G of a second color and the color layers 34B of a third color are similarly formed.

FIG. 4 is a diagram showing the large substrate 42, on which the plurality of color layers 34, each colored one of the plurality of colors, are disposed. The color layers 34 of each color are formed in turn in this embodiment, whereas the color layers 34 of each color may be formed all together.

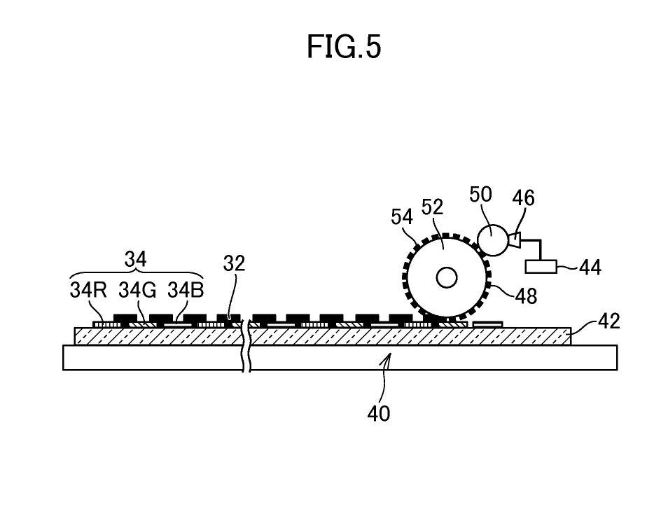

FIG. 5 is a diagram for explaining a process for forming the black matrix 32. In this embodiment, the black matrix 32 is also formed by printing. A printing process similar to that for forming the color layers 34, described above, can be applied to the black matrix 32. The multiple color filter substrate 40, which is yet to be cut into the plurality of color filter substrates 28, is prepared by such a process.

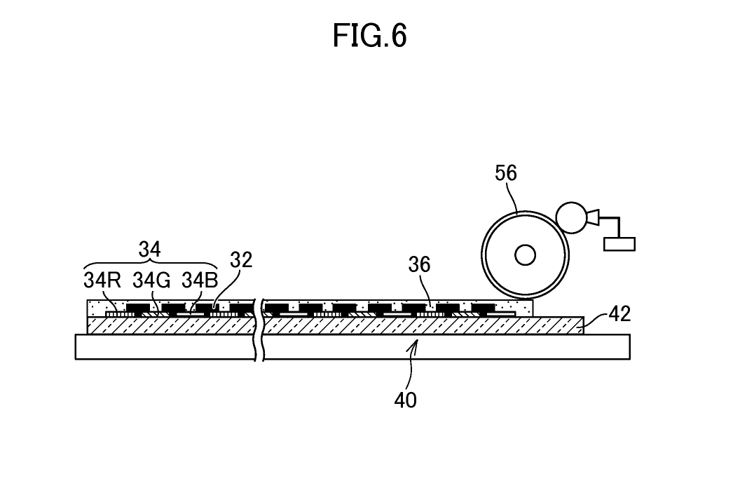

FIG. 6 is a cross-sectional view for explaining a process for forming the adhesive layer 36. FIG. 7 is a perspective view for explaining the process for forming the adhesive layer 36.

In this embodiment, an adhesive 56 is printed on the large substrate 42 to cover the plurality of color layers 34. A printing process similar to that for forming the color layers 34, described above, can be applied to the adhesive layer 36. The adhesive layer 36 is thus formed. The adhesive 56 is preferably ultraviolet curable and slow curing. The adhesive 56 of low viscosity enables the adhesive layer 36 to be formed thinner.

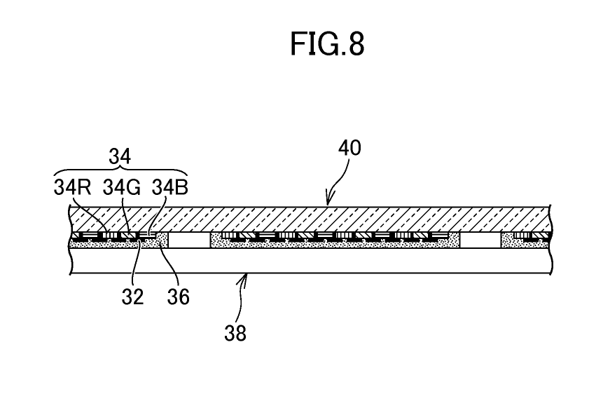

As shown in FIG. 8, the multiple circuit substrate 38 and the multiple color filter substrate 40 are bonded together with the adhesive layer 36. The adhesive layer 36 is then cured by ultraviolet irradiation. The outer surface of the multiple circuit substrate 38 and the outer surface of the multiple color filter substrate 40 may be each thinned by grinding.

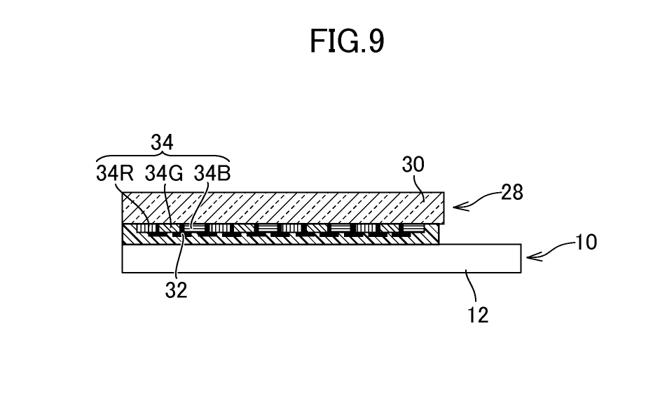

After the multiple circuit substrate 38 and the multiple color filter substrate 40 are bonded together, they are cut into a plurality of bonded pairs of the circuit substrate 10 and color filter substrate 28, as shown in FIG. 9. According to the present embodiment, the adhesive layer 36, which is formed by printing the adhesive 56, can be thinner. Such a thin adhesive layer 36 places the circuit substrate 10 and the color filter substrate 28 closer to each other, thus making it harder for light generated in any pixel to enter the adjacent pixel. This can prevent color crosstalk between adjacent pixels.

While there have been described what are at present considered to be certain embodiments of the invention, it will be understood that various modifications may be made thereto, and it is intended that the appended claims coverall such modifications as fall within the true spirit and scope of the invention.

What is claimed is:

1. A method for manufacturing an organic electroluminescent display device, comprising:
preparing a circuit substrate having an anode, a cathode, an organic electroluminescent film sandwiched between the anode and the cathode, and a sealing film sealing the organic electroluminescent film;
preparing a color filter substrate; and
bonding the circuit substrate and the color filter substrate with an adhesive layer, wherein
the step of preparing the color filter substrate comprises:
disposing a plurality of color layers, each colored one of a plurality of colors, on a substrate; and
printing an adhesive on the substrate to form the adhesive layer covering the plurality of color layers.

2. The method according to claim 1, wherein
the adhesive is slow curing, and
the adhesive layer is cured after the circuit substrate and the color filter substrate are bonded together.

3. The method according to claim 1, wherein
the plurality of color layers are formed by printing.

4. The method according to claim 1, wherein
the step of preparing the color filter substrate further comprises forming a black matrix by printing.

5. The method according to claim 1, further comprising:
preparing a multiple circuit substrate yet to be cut into a plurality of the circuit substrates;
preparing a multiple color filter substrate yet to be cut into a plurality of the color filter substrates;
bonding the multiple circuit substrate and the multiple color filter substrate with the adhesive layer; and
cutting the multiple circuit substrate and the multiple color filter substrate into a plurality of bonded pairs of the circuit substrate and the color filter substrate.
